(19) United States
(12) Patent Application Publication
(10) Pub. No.: US 2014/0191329 A1
(43) Pub. Date: Jul. 10, 2014

(54) METHOD FOR PRODUCING METAL CONTACTS WITHIN AN INTEGRATED CIRCUIT, AND CORRESPONDING INTEGRATED CIRCUIT

(71) Applicant: STMicroelectronics (Rousset) SAS, Rousset (FR)

(72) Inventors: Christian Rivero, Rousset (FR); Roger Delattre, Trets (FR)

(73) Assignee: STMICROELECTRONICS (ROUSSET) SAS, Rousset (FR)

(21) Appl. No.: 14/143,100

(22) Filed: Dec. 30, 2013

(30) Foreign Application Priority Data
Jan. 4, 2013 (FR) 1350070

(51) Int. Cl. H01L 29/66; H01L 29/78

(52) U.S. Cl. CPC H01L 29/665; H01L 29/7845
USPC 257/383; 438/653

(57) ABSTRACT

An integrated circuit includes a MOS transistor having a gate region and source and drain regions separated from the gate region by insulating spacers. At least two metal contact pads respectively contact with two metal silicide regions (for example, a cobalt silicide) which lie within the source and drain regions. The silicide regions are located at the level of lower parts of the two metal contact pads and are separate by a distance from the insulating spacers.

### PRIORITY CLAIM

This application claims priority from French Application for Patent No. 1350070 filed Jan. 4, 2013, the disclosure of which is incorporated by reference.

### TECHNICAL FIELD

The invention relates to integrated circuits, and more particularly to the production of metal contact pads, or more simply contacts, within these integrated circuits.

The invention applies advantageously but without limitation to the production of metal contacts for integrated circuits produced in CMOS technologies higher than 65 nanometers, for example 80 or 90 nanometers, for which cobalt is used in order to produce a metal silicide lying at the interface between the silicon and the metal contact.

The use of metal silicide makes it possible to reduce greatly the value of the electrical access resistance of the contact.

### BACKGROUND

A metal contact makes it possible, for example, to electrically connect a terminal of a component produced in and/or on the substrate of the integrated circuit to the first metal level of this integrated circuit.

The conventional sequence of operations necessary for producing electrical contacts on silicon regions of the integrated circuit in a 90 nm CMOS technology, for example, on source, drain and gate regions of an MOS transistor, is known to the person skilled in the art by the term “SALICIDE” (Self-Aligned siLICIDE), and is as follows.

After an anneal of the regions in question, for example source and drain regions, carried out for example at 1030° C. for 15 seconds, the silicon regions that are not intended to be silicided are protected with a specific mask, generally formed by a bilayer of silicon oxide and silicon nitride. Then, after having carried out amorphization of the silicon, full-wafer deposition of a cobalt/titanium-nitride bilayer is carried out.

A first rapid thermal processing operation (rapid thermal anneal) is subsequently carried out, typically at 530° C. for 30 seconds, so as to form cobalt monosilicide CoSi. A rapid thermal processing operation of this type is known to the person skilled in the art by the acronym RTP (Rapid Thermal Processing) or RTA (Rapid Thermal Annealing).

The cobalt/titanium-nitride bilayer is then removed, and a stop layer, typically of silicon nitride, for the later etching of the contact is deposited.

A dielectric region is then formed with the aid of a dielectric material, for example the one known to the person skilled in the art by the acronym PMD (Pre-Metal Dielectric).

A densifying anneal is subsequently carried out, typically at 830° C. for 20 seconds, which leads to the cobalt monosilicide being converted into cobalt disilicide (CoSi₂).

An orifice is subsequently etched into the dielectric so as to form the location of the future electrical contact.

The orifice opens into the silicided region (CoSi₂). The orifice is subsequently filled with a barrier layer (for example Ti/TiN) surmounted by a filling metal, for example tungsten W.

Besides the fact that such a sequence has a relatively large number of steps, the metal silicide (CoSi₂) obtained is not always uniform. Furthermore, the etching of the orifice in which the metal contact will be formed is a difficult operation, because there is a non-negligible risk of piercing the silicided region, which in this case then leads to a direct metal/silicon contact and therefore an extremely high access resistance.

### SUMMARY

According to one implementation and embodiment, in particular, a method is provided for producing a metal contact, which has a number of steps smaller than that of the prior art in the “SALICIDE” method and leads to a more uniform subjacent silicided region being obtained without risk of piercing this silicided region during the production of the contact, even when there is a metal contact which is inserted at depth into the silicon region in question.

According to one aspect, a method is provided for producing at least one metal contact on a silicon region of an integrated circuit; this production comprises: formation, in a portion of the integrated circuit, for example a dielectric block of the PMD type, of a through-orifice opening into a zone of the silicon region; formation, on the side wall of the orifice and on the zone, of a nickel-free first metal layer, for example comprising cobalt, and formation of an electrically conductive barrier layer, for example a barrier layer comprising titanium nitride, above the first layer; formation, from the metal of the first layer, of a metal silicide under the barrier layer in contact with the silicon zone, and filling of the orifice with a filling metal.

Thus, according to this aspect, the metal silicide is formed locally under the barrier layer after having etched the orifice intended to receive the metal contact. The uniformity of the metal silicide under the contact is thus improved. It also avoids piercing of the metal silicide by the etching of the orifice, since this etching is carried out before the formation of the metal silicide, this being done independently of the depth of the etching of the orifice intended to receive the contact.

It also avoids use of the specific protection mask used in the SALICIDE method, and optionally, depending on the type of anneal used, it is possible to form cobalt monosilicide which, for the same initial cobalt thickness, is a thinner silicide than cobalt disilicide CoSi₂. Consequently, less silicon is consumed and there are lower metal stresses than with cobalt disilicide.

Furthermore, in view of the characteristics of the rapid thermal processing operations conventionally used to form the metal silicide, a nickel-free first metal layer will preferably be used so as to avoid the formation of nickel disilicide NiSi₂, which is extremely resistive.

This being the case, other metal precursors of silicide are possible, for example titanium, which is used particularly in less advanced technologies, so as to obtain for example titanium disilicide (TiSi₂).

The formation of the metal silicide may be carried out before or after filling the orifice with the filling metal.

Depending on the nature of the silicide which is intended to be obtained, one anneal or two successive anneals may be carried out before filling the orifice with the filling metal.

Thus, when the first metal layer comprises cobalt, cobalt monosilicide CoSi can be formed with the aid of a single anneal. It is also possible to carry out two successive anneals so as to form cobalt disilicide CoSi₂. The two successive anneals may, however, be replaced by a single very rapid anneal at high temperature in order to obtain cobalt disilicide CoSi₂.

As a variant, as indicated above, this or these anneals may be carried out after filling the orifice with the filling metal.

In certain cases, the through-orifice (in which the contact will be produced) may open at depth into the zone of the silicon region (for example because of a poorly controlled etch stop) and the formation of the metal silicide then comprises formation of metal silicide in a U-shape between the silicon region and the barrier layer.

According to another aspect, an integrated circuit is provided, comprising at least one metal contact arranged in a first portion of the integrated circuit and having a central metal region covered laterally and in its lower part with an electrically conductive barrier layer, and a nickel-free outer metal layer covering the lateral part of the barrier layer, the first metal contact coming in contact with a silicided region essentially located under the barrier layer at the level of the lower part of the metal contact and comprising a nickel-free metal silicide.

According to one embodiment, the silicided region is essentially located under the metal contact.

As a variant, the silicided region is in a U-shape and is essentially located around the lower part of the metal contact.

The outer layer may comprise cobalt, and the silicided region then comprises cobalt monosilicide CoSi, or alternatively cobalt disilicide CoSi₂.

The breakdown voltage of a transistor, for example an MOS transistor, is in certain cases an important parameter of this transistor, and it may then be advantageous to attempt to have a breakdown voltage which is as high as possible. Furthermore, it has been surprisingly observed that the use of metal contacts with a metal silicide region located under the metal contact and at a distance from the insulating spacers of the transistor made it possible to increase the breakdown voltage of the transistor, without it being necessary to modify the structure of this transistor or to use specific implantation of dopants, this being irrespective of the nature of the metal of the metal silicide.

In addition, according to another aspect, a use in an integrated circuit of metal contacts on active source and drain zones of MOS transistors in order to increase the breakdown voltage of these transistors is provided, each of these metal contacts coming in contact with a silicided region of the corresponding active zone of the transistor, the silicided region being essentially located at the level of the lower part of the metal contact, at a distance from the insulating spacers of these transistors, and comprising a preferably nickel-free metal silicide; each metal contact has, for example, a central metal region covered laterally and in its lower part with an electrically conductive barrier layer, and a preferably nickel-free outer metal layer covering the lateral part of the barrier layer.

### BRIEF DESCRIPTION OF THE DRAWINGS

Other advantages and characteristics of the invention will become apparent on studying the detailed description of implementations and embodiments, which imply no limitation, and the appended drawings, in which:

FIGS. 1 to 4 schematically illustrate a first implementation of a method,

FIGS. 5 to 7 schematically illustrate another implementation of a method,

FIGS. 8 to 11 schematically illustrate other implementations of the method,

FIG. 12 illustrates an integrated circuit having silicided regions according to the prior art, and

FIGS. 13 and 14 illustrate different embodiments of an integrated circuit.

### DETAILED DESCRIPTION OF THE DRAWINGS

In FIG. 1, the reference RS1 denotes a silicon region, for example an active zone (drain, source or gate) of an MOS transistor of an integrated circuit.

It is assumed in this example that the integrated circuit is produced in a 90 nanometer CMOS technology, for which cobalt is conventionally used to form the silicide regions.

After a thermal anneal of the region RS1, for example at 1030° C. for 15 seconds, and amorphization of the silicon, a portion PRT1 is formed on this region RS1, typically a dielectric portion formed by a pre-metal dielectric, that is to say a dielectric separating the silicon region RS1 from the first metallization level of the integrated circuit.

This dielectric is, for example, an oxide known to the person skilled in the art by the acronym BPSG: BoroPhospho Silicate Glass.

A densifying anneal of the portion PRT1 is subsequently carried out, typically at 830° C. for 20 seconds.

An orifice OR1 is then formed in the portion PRT1 by a conventional operation of photolithography and etching.

This orifice OR1 passes through this portion PRT1 and opens into a zone Z1 of the silicon region RS1.

When the integrated circuit is produced in a 90 nanometer CMOS technology, the diameter of this orifice OR1 is typically equal to 110 nanometers.

On the side walls of the orifice OR1 and on the zone Z1, as well as on the upper face of the portion PRT1, a stack is then formed comprising a first layer C1, for example a layer of cobalt, surmounted by a barrier layer C2, for example a layer of titanium nitride TiN.

The thickness of the cobalt layer is, for example, 7 nanometers, while the thickness of the titanium nitride layer is, for example, of the order of 10 nanometers.

The formation of the layers C1 and C2 may be carried out, for example, by conventional physical vapour deposition which is well known by those skilled in the art.

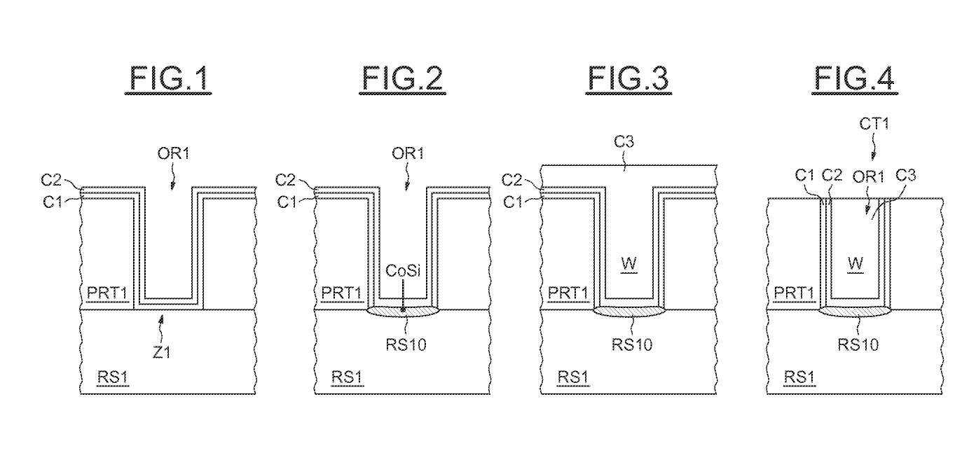

In the following step, which is illustrated in FIG. 2, a cobalt silicide is formed, and more precisely cobalt monosilicide CoSi. This silicided region RS10 is obtained by an anneal carried out, for example, at 500° C. for 30 seconds. The silicided region RS10 is obtained from the metal (cobalt) of the metal layer C1.

It can be seen in FIG. 2 that the silicided region RS10 is essentially located under the barrier layer C2.

The next step, which is illustrated in FIG. 3, consists in filling the orifice OR1 with a filling metal, here tungsten W. This filling is carried out here by conventional chemical vapor deposition, which is known by those skilled in the art, of a layer C3 of the metal in question, here tungsten. The layer C3 also covers the stack of layers C1 and C2 arranged above the upper face of the portion PRT1 outside the orifice.

It should also be noted here that the layers C1 and C2 remain on the side walls of the orifice OR1 after formation of the metal silicide. The layer C2 acts as a barrier layer in order to avoid diffusion of the metal into the portion PRT1 (dielectric), and the remainder of the first layer C1 then contributes to the barrier function against diffusion of the metal into the portion PRT1.

Furthermore, when the filling metal is W, the use of cobalt in the Co/TiN barrier instead of a Ti/TiN barrier is particularly advantageous because titanium often gives rise to so-called “popcorn” problems when fluorine (coming from the WF₆ used for the CVD deposition of W) passes through the TiN and reacts with the titanium to form gaseous TiF₆.

The next step, which is illustrated in FIG. 4, comprises removal of the stack of layers C1, C2, C3 outside the filled orifice OR1, as well as removal of the excess of metal above this orifice, so as to form a metal contact CT1. The removal of the layers C1, C2 and C3 may be carried out conventionally by chemical-mechanical polishing (CMP).

As illustrated in FIG. 4, an integrated circuit is therefore obtained comprising at least one metal contact CT1 arranged in the portion PRT1 of the integrated circuit, this metal contact CT1 comprising a central metal region C3 (typically of tungsten) covered laterally and in its lower part with an electrically conductive barrier layer C2. The metal contact CT1 also comprises an outer layer C1, here of cobalt, covering the lateral part of the barrier layer C2.

This first metal contact CT1 comes in contact with the region RS10 comprising a metal silicide, here cobalt monosilicide CoSi, this region RS10 being located under the lower part of the barrier layer C2.

It can therefore be seen that such a contact has been obtained without the need for a specific mask protecting the regions not intended to be silicided. Furthermore, the region RS10 is uniform under the contact CT1. It is also easy to produce cobalt monosilicide, which is thinner than cobalt disilicide CoSi₂. For this reason, there is less consumption of silicon and a lower mechanical stress than in the case of CoSi₂.

There is also no problem of piercing the silicided region RS10, since this region RS10 is formed after etching the orifice OR1.

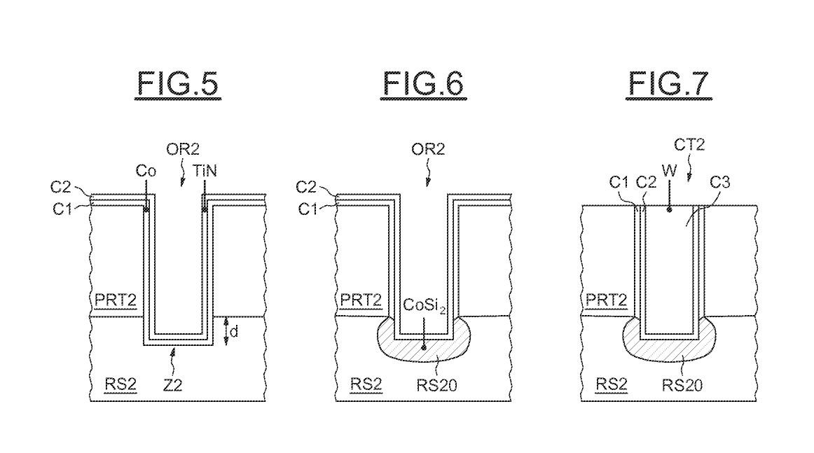

FIGS. 5 to 7 illustrate another implementation and embodiment.

Only the differences between FIGS. 5 to 7 and FIGS. 1 to 4 will now be described, for the sake of simplification.

In FIG. 5, the orifice OR2 is etched into a portion PRT2 and opens at depth into a zone Z2 of the silicon region RS2. The depth of etching into the silicon region RS2 is equal to d.

The layers C1 and C2 are subsequently formed in a way similar to that described above.

As illustrated in FIG. 6, a silicided region RS20 is then formed from the metal of the layer C1 (here cobalt), which region has the shape of a U which is essentially located around the lower part of the barrier layer C2.

There are several possibilities for forming this metal silicide RS20.

Either a single anneal is carried out at 530° C. for 30 seconds and cobalt monosilicide CoSi is then obtained in the region RS20.

Or cobalt monosilicide CoSi is formed first then a second anneal is carried out, in the case in point a rapid conversion anneal, for example at 790° C. for 20 seconds, so as to form cobalt disilicide CoSi₂.

As a variant, the anneal may be carried out directly at 790° C. for 20 seconds in order to obtain CoSi₂ directly.

In a way similar to that described above with reference to FIGS. 3 and 4, the contact CT2 is then completed by filling the orifice OR2 with a filling metal, typically tungsten W, then chemical-mechanical polishing is carried out so as to obtain the contact CT2 illustrated in FIG. 7.

In this FIG. 7, the silicided region RS20 is furthermore essentially located around the lower part of the contact CT2 under the barrier layer CT2.

Here again, it can also be seen that even in the event of overetching d of the orifice OR2, there is no risk of piercing any silicided region since this silicided region is formed after etching the orifice OR2.

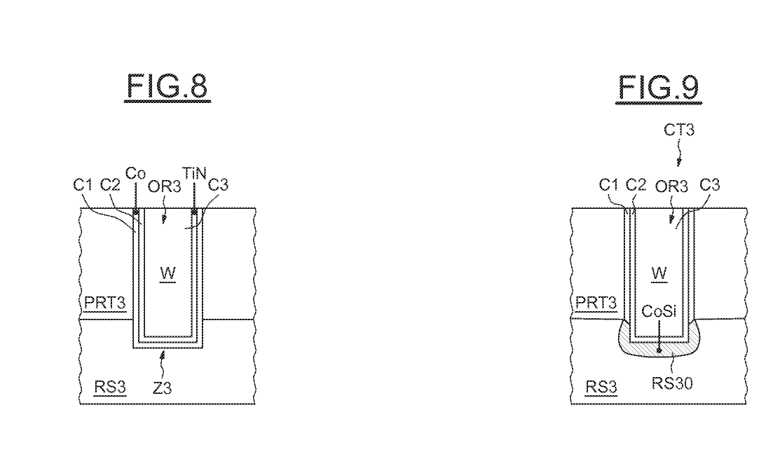

The implementation and embodiment illustrated in FIGS. 8 and 9 differs from those which have just been described in that, this time, the metal silicide is formed after filling the orifice with the filling metal.

More precisely, as illustrated in FIG. 8, in a way similar to that described above, an orifice OR3 is formed by etching through the portion PRT3 of the integrated circuit so that this orifice OR3 opens into a zone Z3 of the silicided region RS3. Here, the orifice OR3 opens at depth into the region RS3, although this is not essential.

The orifice OR3 is subsequently filled with the metal layer C3 (here of tungsten W), then chemical-mechanical polishing is carried out.

Subsequently, as illustrated in FIG. 9, the region RS30 of metal silicide, which in this case is cobalt monosilicide CoSi, is formed. This region RS30 is in the shape of a U around the lower part of the contact CT3, since the etching of the orifice OR3 is carried out at depth into the silicon region RS3.

It should be noted that, in this case, the chemical-mechanical polishing operation could also have been carried out after formation of the silicided region RS30.

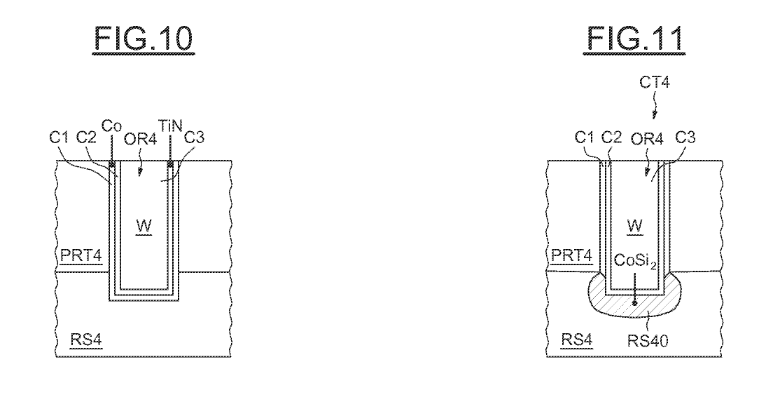

In the implementation and embodiment illustrated in FIGS. 10 and 11, it is cobalt disilicide which is formed this time in the silicided region RS40, which is U-shaped and surrounds the lower part of the contact CT4. Here again, the orifice OR4 is filled with tungsten W.

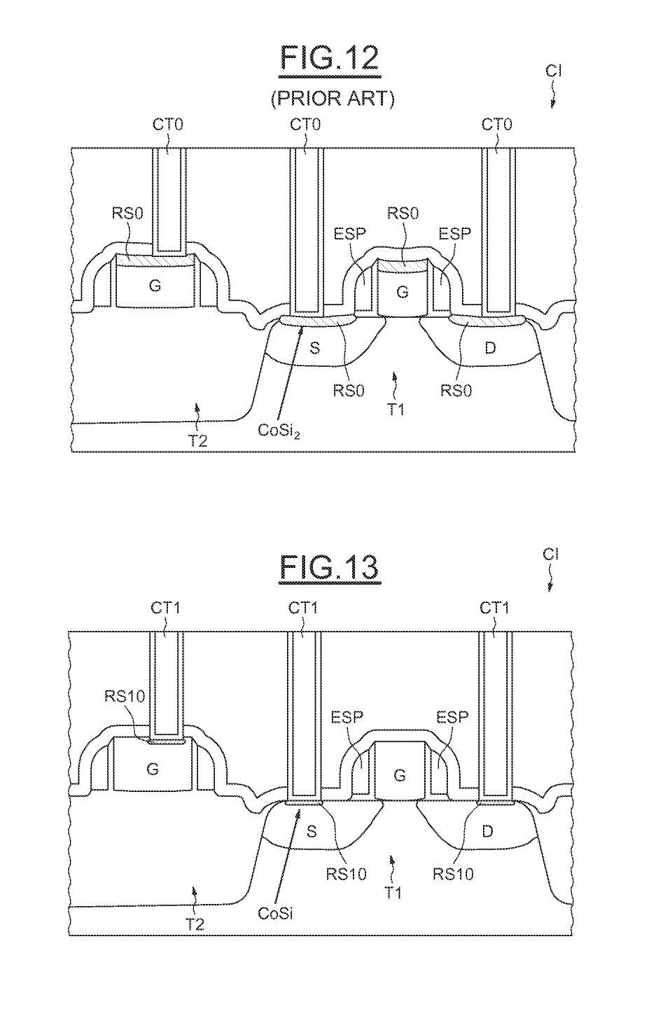

FIG. 12 schematically illustrates an integrated circuit of the prior art, comprising a plurality of transistors (here, two MOS transistors T1 and T2) having silicided regions RS0 on the active source, drain and gate zones of these transistors T1 and T2. These silicided regions are formed in this case by cobalt disilicide CoSi₂ and have been formed in a conventional way by using a sequence of steps of the prior art, comprising in particular production of the contacts CT0 after formation of the silicide regions RS0.

It can be seen in this integrated circuit of the prior art that the silicided regions RS0 are not essentially located under the contacts CT0 but extend over a sizeable part of the active source and drain zones, as well as over all of the gate zone G, and in particular as far as the base of the insulating spacers ESP. As is well known, these insulating spacers are lateral insulating regions making it possible to electrically insulate the gate region from the source and drain regions.

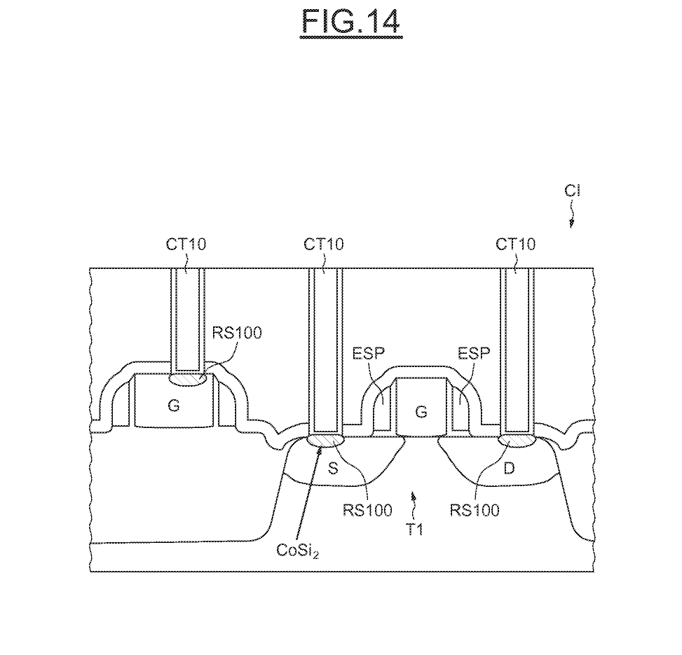

Conversely, according to one embodiment of an integrated circuit according to the invention, as illustrated in FIG. 13, the silicided regions RS10 are in this case essentially located under the contact CT1 and at a distance from the spacers ESP. Furthermore, these silicided regions may be formed by cobalt monosilicide CoSi (region RS10) or alternatively cobalt disilicide CoSi₂, as is the case in FIG. 14, the silicided regions RS100 still being located under the contacts CT10.

Furthermore, the fact of having silicided regions at least on the source and drain regions (regardless of the metal and the composition of the metal silicide) and located at a distance from the spacers makes it possible to increase the value of the breakdown voltage of these transistors, for example of the order of 1 volt, and to do so without modification of the structure or the design of the transistor and without specific implantation of dopants. This is particularly advantageous in particular when the transistors are the high-voltage transistors used in EEPROM memories.

What is claimed is:

1. A method, comprising:
forming an orifice in a portion of an integrated circuit, said orifice opening into a zone of a silicon region of the integrated circuit;
forming a nickel-free first metal layer on a side wall of the orifice and on said zone;
forming an electrically conductive barrier layer above the nickel-free first metal layer;
forming a metal silicide from the metal of the nickel-free first metal layer under the barrier layer in contact with the silicon zone; and
filling the orifice with a filling metal covering the electrically conductive barrier layer.

2. The method according to claim 1, wherein forming the metal silicide comprises performing at least one anneal carried out before the filling of the orifice.

3. The method according to claim 2, wherein forming the metal silicide comprises performing two successive anneals carried out before the filling of the orifice.

4. The method according to claim 2, wherein the first metal layer comprises cobalt, and forming the metal silicide comprises forming cobalt monosilicide CoSi.

5. The method according to claim 2, wherein the first metal layer comprises cobalt, and forming the metal silicide comprises forming cobalt disilicide CoSi2.

6. The method according to claim 1, wherein forming the metal silicide comprises performing at least one anneal carried out after the filling of the orifice.

7. The method according to claim 6, wherein forming the metal silicide comprises performing two successive anneals carried out after the filling of the orifice.

8. The method according to claim 6, wherein the first metal layer comprises cobalt, and forming the metal silicide comprises forming cobalt monosilicide CoSi.

9. Method according to claim 6, wherein the first metal layer comprises cobalt, and forming the metal silicide comprises forming cobalt disilicide CoSi₂.

10. The method according to claim 1, wherein forming the electrically conductive barrier layer comprises forming a layer of titanium nitride TiN, and the filling metal comprises tungsten.

11. The method according to claim 1, wherein forming the first metal layer and forming the barrier layer also comprise covering the first integrated circuit portion with the first metal layer surmounted by the barrier layer, and wherein filling the orifice also comprises covering the first metal layer surmounted by the barrier layer with a layer of the filling metal to form a stack of layers, and removing the stack of layers from the first portion outside the filled first orifice.

12. The method according to claim 1, wherein the through-orifice is formed opening at depth into the zone of the silicon region, and forming the metal silicide comprises forming metal silicide having a U-shape between the silicon region and the barrier layer.

13. An integrated circuit, comprising:
at least one metal contact arranged in a first portion of the integrated circuit and having:
a central metal region covered laterally and in a lower part thereof with an electrically conductive barrier layer, and
a nickel-free outer metal layer covering the lateral part of the barrier layer,
said metal contact coming in contact with a silicided region essentially located under the barrier layer at the level of the lower part of the metal contact and comprising a nickel-free metal silicide.

14. The integrated circuit of claim 13, wherein the integrated circuit includes at least one MOS transistor having a gate region and source and drain regions separated from the gate region by insulating spacers, and the at least one metal contact comprises at two metal contacts in contact with silicided regions of the source and drain regions, said silicided regions located at the level of lower parts of the two metal contacts and at a distance from the insulating spacers.

15. The integrated circuit according to claim 13, wherein each contact has a central metal region covered laterally and in its lower part with an electrically conductive barrier layer, and an outer metal layer covering the lateral part of the barrier layer, the silicided region being essentially located under the barrier layer of the corresponding metal contact.

16. The integrated circuit according to claim 15, wherein the outer metal layer comprises cobalt.

17. The integrated circuit according to claim 15, wherein the barrier layer comprises titanium nitride and the metal of the central region is tungsten.

18. The integrated circuit according to claim 14, wherein the silicided region is essentially located under the metal contact.

19. The integrated circuit according to claim 14, wherein the silicided region has a U-shape and is essentially located around the lower part of the metal contact.

20. The integrated circuit according to claim 14, wherein the silicided region comprises one of cobalt monosilicide CoSi or cobalt disilicide CoSi₂.
